(19) United States
(12) Patent Application Publication
(10) Pub. No.: US 2008/0169480 A1
(43) Pub. Date: Jul. 17, 2008

(54) Optoelectronic device package and packaging method thereof

(75) Inventors: Jui-Ping Weng, Miaoli (TW); Hsiao-Wen Lee, Hsinchu (TW)

Correspondence Address: Joe McKinney Muncy, PO Box 1364, Fairfax, VA, 22038-1364, US

(73) Assignee: VisEra Technologies Company Limited

(21) Appl. No.: 11/652,060

(22) Filed: Jan. 11, 2007

(51) Int. Cl. H01L 33/00

(52) U.S. Cl. 257/98; 438/27; 257/E33.059

(57) ABSTRACT

An optoelectronic device package. The optoelectronic device package includes a substrate, a reflector formed on a first plane of the substrate, a cover bonded to the reflector to form a closed space, a plurality of microlenses formed on a first plane of the cover, a phosphor film formed on a second plane of the cover within the closed space, a thermal-conductive film formed on a second plane of the substrate, an electrode formed on the sidewall and the second plane of the substrate uncovered by the thermal-conductive film, and an optoelectronic device formed on the first plane of the substrate within the closed space. The invention also provides a method of packaging the optoelectronic device.

### BACKGROUND OF THE INVENTION

1. Field of the Invention

The invention relates to a semiconductor device, and in particular to an optoelectronic device package and a packaging method thereof.

2. Description of the Related Art

Currently, packaging of surface mount devices of light-emission diodes (SMD LED) is mainly divided into circuit and leadframe types. The leadframe SMD LED uses a metallic leadframe as substrate and injection molding for plastic grooves or compression molding, followed by cutting into SMD LED, as shown in FIG. 1. FIG. 1 is a structural diagram of a conventional metal leadframe SMD LED (commonly referred to as TOOPLED type). In the manufacturing process, heat resistant plastic resin (PPS) is used for injection molding to form a groove 2 with metal leadframe, followed by die bonding 3, wire bonding 4 and encapsulation 5 etc. The main packaging material thereof is plastic or epoxy. Circuit SMD LED uses a composite circuit board as substrate, followed by compression molding and cutting into SMD LED, as shown in FIG. 2. FIG. 2 is a structural diagram of a conventional circuit board SMD LED. During manufacture, the LED chip is fixed to substrate 6 and bond electrode wire 4, followed by die casting to form encapsulation 5, followed by cutting to SMD LED. The major packaging material thereof is transparent epoxy.

SMD LED produced by both methods exhibit insufficient heat resistance, especially when SMD components connected with board circuits pass through high temperature furnace (at about 250˜300° C.), the packaging resin for SMD LED lacks sufficient heat resistance. Since the packaging resin has a Tg temperature of only about 120° C. and a different coefficient of thermal expansion from that of the substrates or the leadframe, unusual defects often occur.

Another shortcoming is poor heat dissipation, due to poor thermal conductance of the packaging resins and substrates. Since the LED itself is a small heat-generating object, temperature increase affects emission efficiency and quality. Also encountered is reduction of emission intensity from miniaturization without groove reflector by more than one-fold (compared at an emission angle of 30°), due to difficulty in employing conventional process to make groove reflectors for SMD LED. Poor heat resistance and heat dissipation and difficulty in minimizing groove reflectors continue to present problems in conventional SMD LED fabrication.

### BRIEF SUMMARY OF THE INVENTION

The invention provides an optoelectronic device package comprising a substrate, a reflector formed on a first plane of the substrate, a cover bonded to the reflector to form a closed space, a plurality of microlenses formed on a first plane of the cover, a phosphor film formed on a second plane of the cover within the closed space, a thermal-conductive film formed on a second plane of the substrate, an electrode formed on the sidewall and the second plane of the substrate uncovered by the thermal-conductive film, and an optoelectronic device formed on the first plane of the substrate within the closed space.

The invention also provides a method of packaging an optoelectronic device, in which substrate is provided. A reflector is formed on a first plane of the substrate. An electrode is formed on the sidewall and a portion of a second plane of the substrate. A thermal-conductive film is formed on the second plane of the substrate uncovered by the electrode. An optoelectronic device is formed on the first plane of the substrate. A cover is provided. A plurality of microlenses are formed on a first plane of the cover. A phosphor film is formed on a second plane of the cover. The cover is bonded to the reflector to form a closed space containing the phosphor film and the optoelectronic device.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a cross section of a related leadframe-type light-emission diode package.

FIG. 2 is a cross section of a related circuit-type light-emission diode package.

FIG. 3 is a cross section of an optoelectronic device package of the invention.

FIGS. 4A˜4L are cross sections of a method of packaging an optoelectronic device of the invention.

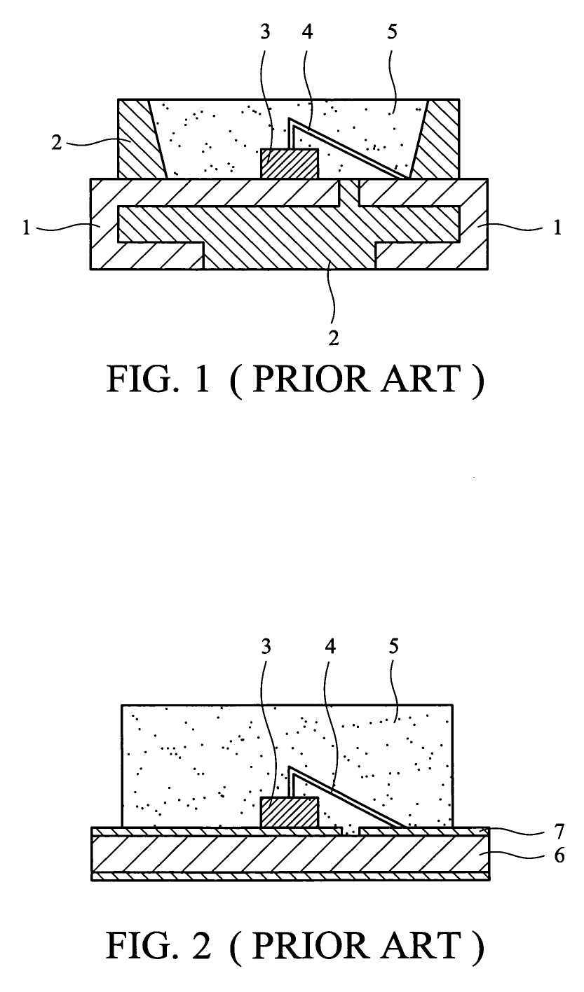

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

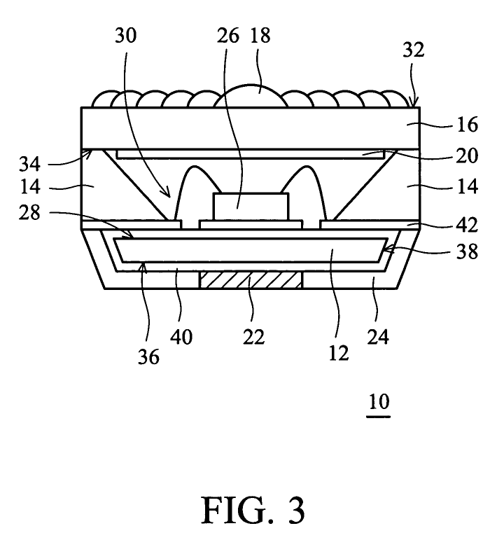

An optoelectronic device package of the invention is shown in FIG. 3. The optoelectronic device package 10 comprises a substrate 12, a reflector 14, a cover 16, a plurality of microlenses 18, a phosphor film 20, a thermal-conductive film 22, an electrode 24, and an optoelectronic device 26.

The reflector 14 is formed on a first plane 28 of the substrate 12. The cover 16 is bonded to the reflector 14 to form a closed space 30. The microlenses 18 are formed on a first plane 32 of the cover 16. The phosphor film 20 is formed on a second plane 34 of the cover 16 within the closed space 30. The thermal-conductive film 22 is formed on a second plane 36 of the substrate 12. The electrode 24 is formed on the sidewall 38 and the second plane 36 of the substrate 12 uncovered by the thermal-conductive film 22. The optoelectronic device 26 is formed on the first plane 28 of the substrate 12 within the closed space 30. The anode and cathode (not shown) of the optoelectronic device 26 are respectively electrically connected to the electrode 24.

The substrate 12 and the reflector 14 may comprise silicon. The cover 16 is transparent and may comprise glass or plastic such as high-temperature resistant plastic. The closed space 30 may be a vacuum or filled with a transparent colloid such as epoxy or air. The thermal-conductive film 22 may comprise various thermal-conductive materials, preferably a diamond film. The optoelectronic device 26 may be a semiconductor light source such as light-emission diode (LED) light source, laser light source, and organic light-emission diode (OLED) light source.

The optoelectronic device package 10 may further comprise electrostatic discharge (ESD) protection (not shown) formed on the substrate 12. The reflector 14 may further comprise a high-reflective metal film (not shown) formed thereon to improve the reflection thereof. Additionally, an isolation layer 40 is formed on the surface of the substrate 12. A conductive layer 42 is formed between the reflector 14 and the optoelectronic device 26 and the substrate 12. The optoelectronic device package 10 is a wafer level package (WLP).

Advantageously, the microlenses 18 and the phosphor film 20 are integrated on the cover 16. The thermal-conductive film 22, the electrode 24, and the electrostatic discharge (ESD) protection (not shown) are integrated on the substrate 12. The microlenses 18 formed on the cover 16 improve transmission and uniformity of light and the groove reflector 14 increases emission intensity. An optimal reliability of the optoelectronic device package 10 is achieved during fabrication due to use of high-temperature package materials such as glass and materials of similar coefficients of thermal expansion (CTE) of the reflector 14 and the cover 16, providing sufficient heat resistance. The thermal-conductive film 22 provides a superior thermal dissipation than silicon. The optoelectronic device 26 is electrically connected to the electrode 24 formed on the sidewall 38 and bottom 36 of the substrate 12 through the conductive layer 42 without formation of through holes in the substrate, significantly reducing cost. Additionally, mass production is achieved due to reduced package size.

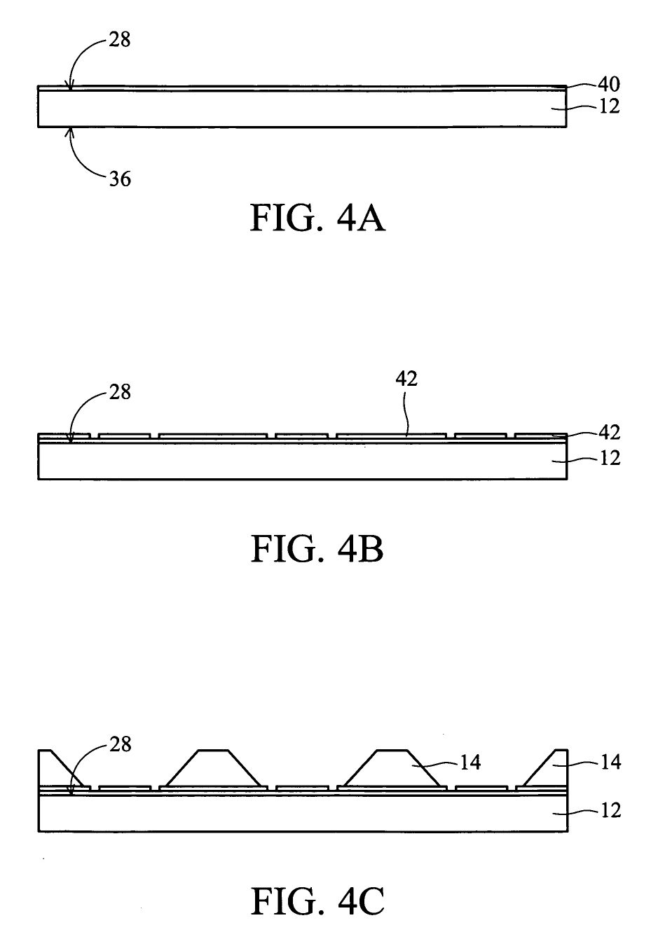

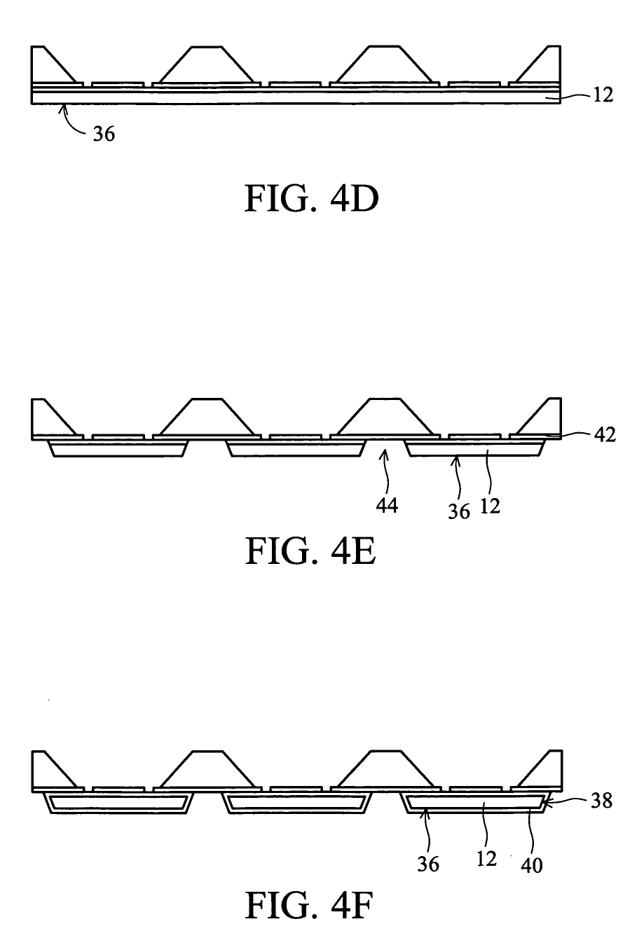

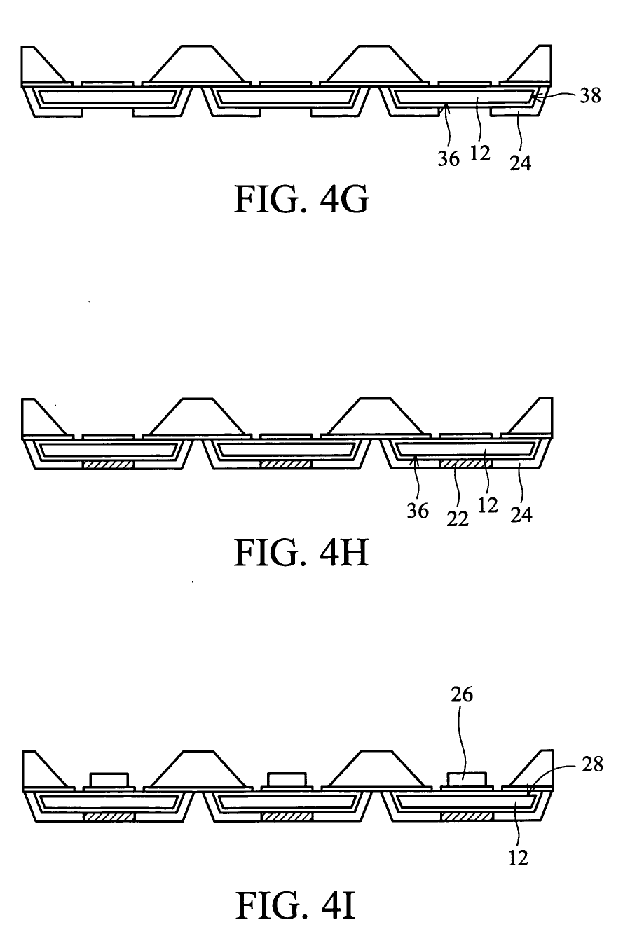

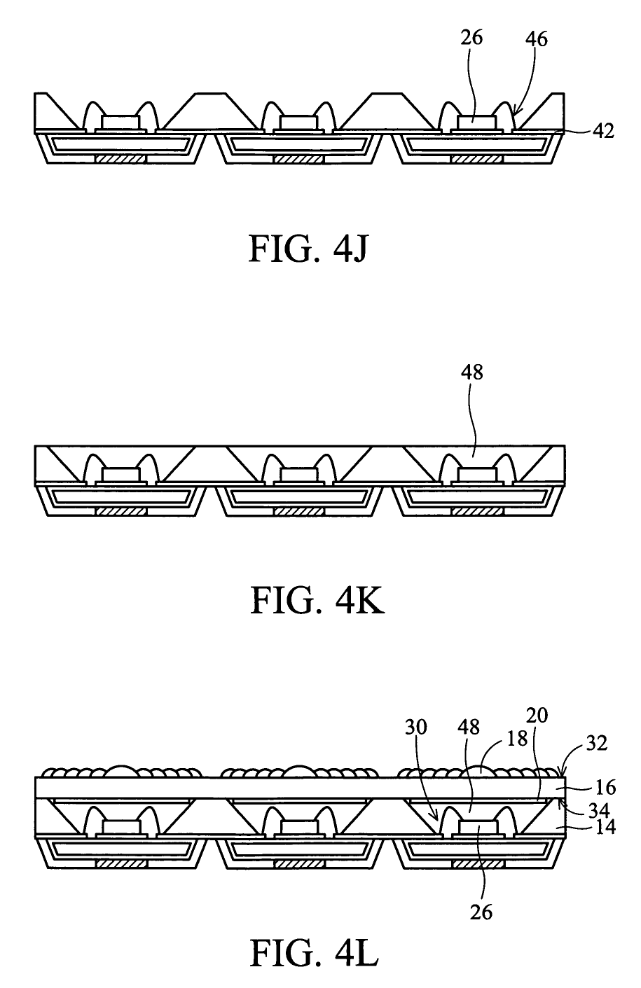

A method of packaging an optoelectronic device of the invention is disclosed in FIGS. 4A˜4L. Referring to FIG. 4A, a substrate 12 having a first plane 28 and a second plane 36 is provided. Next, an isolation layer 40 is formed on the first plane 28 of the substrate 12.

Referring to FIG. 4B, a patterned conductive layer 42 is then formed on the first plane 28 of the substrate 12.

Next, a substrate (not shown) is bonded on the first plane 28 of the substrate 12 and etched to form a reflector 14, as shown in FIG. 4C. To improve reflection, a metal film (not shown) may further be formed on the reflector 14.

The substrate 12 is then ground from the second plane 36 to reduce the thickness thereof, as shown in FIG. 4D.

Next, the substrate 12 is etched from the second plane 36 to expose a portion of the conductive layer 42, forming a notch 44, as shown in FIG. 4E.

Referring to FIG. 4F, an isolation layer 40 is then formed on the sidewall 38 and the second plane 36 of the substrate 12.

Next, an electrode 24 is formed on the sidewall 38 and a portion of the second plane 36 of the substrate 12, as shown in FIG. 4G.

Referring to FIG. 4H, a thermal-conductive film 22 is then formed on the second plane 36 of the substrate 12 uncovered by the electrode 24.

Next, an optoelectronic device 26 is formed on the first plane 28 of the substrate 12, as shown in FIG. 4I. The optoelectronic device 26 is attached to the substrate 12 by process such as flip chip.

Referring to FIG. 4J, wire bonding 46 is then performed to connect the optoelectronic device 26 and the conductive layer 42.

Next, referring to FIG. 4K, a transparent colloid 48 is filled and levels the structure as shown in FIG. 4J.

A cover 16 with a plurality of microlenses 18 and a phosphor film 20 formed thereon is bonded to the reflector 14 to form a closed space 30 filled with the transparent colloid 48, as shown in FIG. 4L. As shown, the cover 16 is provided. The microlenses 18 are then formed on a first plane 32 of the cover 16 by methods such as a mold. Next, a phosphor film 20 is formed on a second plane 34 of the cover 16. The closed space 30 contains the phosphor film 20 and the optoelectronic device 26. To protect the optoelectronic device 26 from high voltage, electrostatic discharge (ESD) protection (not shown) may further be formed on the substrate 12.

Finally, the structure as shown in FIG. 4L is diced to form a plurality of small size packages.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An optoelectronic device package, comprising:
a substrate;
a reflector formed on a first plane of the substrate;
a cover bonded to the reflector to form a closed space;
a plurality of microlenses formed on a first plane of the cover;
a phosphor film formed on a second plane of the cover within the closed space;
a thermal-conductive film formed on a second plane of the substrate;
an electrode formed on the sidewall and the second plane of the substrate uncovered by the thermal-conductive film; and
an optoelectronic device formed on the first plane of the substrate within the closed space.

2. The optoelectronic device package as claimed in claim 1, wherein the substrate comprises silicon.

3. The optoelectronic device package as claimed in claim 1, wherein the reflector comprises silicon.

4. The optoelectronic device package as claimed in claim 1, wherein the cover comprises glass or plastic.

5. The optoelectronic device package as claimed in claim 1, wherein the cover is transparent.

6. The optoelectronic device package as claimed in claim 1, wherein the thermal-conductive film is a diamond film.

7. The optoelectronic device package as claimed in claim 1, wherein the optoelectronic device is a semiconductor light source.

8. The optoelectronic device package as claimed in claim 7, wherein the semiconductor light source comprises light-emission diode (LED) light source, laser light source, and organic light-emission diode (OLED) light source.

9. The optoelectronic device package as claimed in claim 1, wherein the optoelectronic device is electrically connected to the electrode.

10. The optoelectronic device package as claimed in claim 1, further comprising electrostatic discharge (ESD) protection formed on the substrate.

11. The optoelectronic device package as claimed in claim 1, further comprising a transparent colloid filled in the closed space.

12. The optoelectronic device package as claimed in claim 11, wherein the transparent colloid comprises epoxy or air.

13. The optoelectronic device package as claimed in claim 1, wherein the closed space is a vacuum.

14. The optoelectronic device package as claimed in claim 1, further comprising a metal film formed on the reflector.

15. The optoelectronic device package as claimed in claim 1, further comprising a conductive layer formed between the reflector and optoelectronic device and the substrate.

16. The optoelectronic device package as claimed in claim 1, further comprising an isolation layer formed on the surface of the substrate.

17. The optoelectronic device package as claimed in claim 1, wherein the optoelectronic device package is a wafer level package.

18. A method of packaging an optoelectronic device, comprising:
providing a substrate;
forming a reflector on a first plane of the substrate;
forming an electrode on the sidewall and a portion of a second plane of the substrate;
forming a thermal-conductive film on the second plane of the substrate uncovered by the electrode;
forming an optoelectronic device on the first plane of the substrate;
providing a cover;
forming a plurality of microlenses on a first plane of the cover;
forming a phosphor film on a second plane of the cover; and
bonding the cover to the reflector to form a closed space containing the phosphor film and the optoelectronic device.

19. The method of packaging an optoelectronic device as claimed in claim 18, wherein the microlenses are formed on the cover by a mold.

20. The method of packaging an optoelectronic device as claimed in claim 18, wherein the optoelectronic device is formed on the substrate by flip chip process.

21. The method of packaging an optoelectronic device as claimed in claim 18, further comprising forming electrostatic discharge (ESD) protection on the substrate.

22. The method of packaging an optoelectronic device as claimed in claim 18, further comprising filling a transparent colloid before the cover is bonded to the reflector.

23. The method of packaging an optoelectronic device as claimed in claim 18, further comprising forming a metal film on the reflector.

24. The method of packaging an optoelectronic device as claimed in claim 18, further comprising forming a conductive layer between the reflector and optoelectronic device and the substrate.

25. The method of packaging an optoelectronic device as claimed in claim 18, further comprising forming an isolation layer on the surface of the substrate.
